(19) United States
(12) Patent Application Publication
(10) Pub. No.: US 2006/0113062 A1
(43) Pub. Date: Jun. 1, 2006

(54) Radiating fin assembly

(76) Inventor: Johnson Yang, Jhonghe City (TW)

Correspondence Address: CHARLES E. BAXLEY, ESQ., 90 JOHN STREET, THIRD FLOOR, NEW YORK, NY, 10038, US

(21) Appl. No.: 11/290,383

(22) Filed: Nov. 29, 2005

(30) Foreign Application Priority Data
Dec. 1, 2004 (TW) 093219349

(51) Int. Cl. H05K 7/20

(52) U.S. Cl. 165/80.3; 165/185; 361/704

(57) ABSTRACT

A radiating fin assembly comprises a plurality of radiating fins stacked together, wherein a folding edge is formed on opposite sides of the radiating fins, at both ends of the folding edge is formed a locking protrusion and a neck portion, a flexible slot is defined in the folding edge and located at both sides of the locking protrusion, and a plurality of notches are defined in the respective radiating fins, so that locking protrusions of one radiating fin are allowed to be engaged in the notches of another radiating fin. A flexible hook is formed on each of the locking protrusions and located correspondingly to a undersurface of the radiating fin, a rib is disposed on the flexible hook and connected to the locking protrusion, and at both sides of the respective locking protrusions and the notches are correspondingly arranged a plurality of positioning members.

### BACKGROUND OF THE INVENTION

1. Field of the Invention

The present invention relates to a radiating fin, and more particularly to a radiating fin assembly that can be assembled and disassembled easily without distortion.

2. Description of the Prior Art

A conventional radiating fin 10 as shown in FIG. 1 comprises a plurality of locking protrusions 12 formed on the folding edges 11 thereof, a notch 14 is defined in the edge of the locking protrusions 12 so that two radiating fins 10 can be assembled together through the engagement of the locking protrusions 12 and the notch 14. However, at the front end of the conventional locking protrusions 12 usually are formed differently shaped fastening lugs 13. After two radiating fins 10 are stacked together, the user has to bend the fastening lug 13 and make it abut against another surface of the notch 14, so that the radiating fins 10 can be assembled each firmly. However, such conventional radiating fin still has some disadvantages as follows:

First, it may have its own advantage if the fastening lug 13 is engaged with the other surface of the notch 14, however, such arrangement doesn't facilitate assembly and disassembly.

Second, the user has to bend the fastening lug 13, and this will cause permanent deformation to the fastening lug 13. When the user disassembles the radiating fin 10, although the already distorted fastening lug 13 can be bent again, it will be damaged and cannot be used again. Even worse, if the fastening lug 13 was bent inappropriately, it will adversely affect the stability of the radiating fin assembly (the parallel degree of the radiating fins will be distorted), and as a result, the rate of heat dissipation will be reduced.

Third, the stability of the conventional radiating fin fully depends on the engagement between the fin 12 and the notch 14, and the goodness of fit between the fin 12 and the notch 14 is determined by the consistency of the bending of the fastening lug 13. Therefore, the conventional radiating fin still needs to be improved in terms of stability, and the problems of loose engagement and distortion in parallel degree are also hard to be avoided.

The present invention has arisen to mitigate and/or obviate the afore-described disadvantages.

### SUMMARY OF THE INVENTION

The primary objective of the present invention is to provide a radiating fin assembly that can be assembled/disassembled easily and can be used repeatedly, wherein a folding edge is formed at opposite sides of the radiating fin, respectively, and a flexible slot is defined in the folding edge and located at both sides of the locking protrusion. A plurality of notches are defined in the radiating fin and located correspondingly to the locking protrusions. During assembly, the respective components of the present invention can be prevented from distortion and can be used repeatedly. In addition, the flexible hooks can enable the radiating fins to be assembled more easily.

The secondary objective of the present invention is to provide a radiating fin assembly that has an improved stability and a high parallel degree. The flexible connection between the hook and the locking protrusion can prevent distortion of parallel degree. Furthermore, a plurality of positioning members is arranged on the radiating fins for prevention of over-distortion and deviation. Thereby stability of the radiating fin assembly of the present invention is improved, and the problems of loose engagement and distortion in parallel degree also can be eliminated.

The present invention will become more obvious from the following description when taken in connection with the accompanying drawings, which show, for purpose of illustrations only, the preferred embodiments in accordance with the present invention.

### BRIEF DESCRIPTION OF THE DRAWINGS

FIG. 1 is an exploded view of a conventional radiating flange;

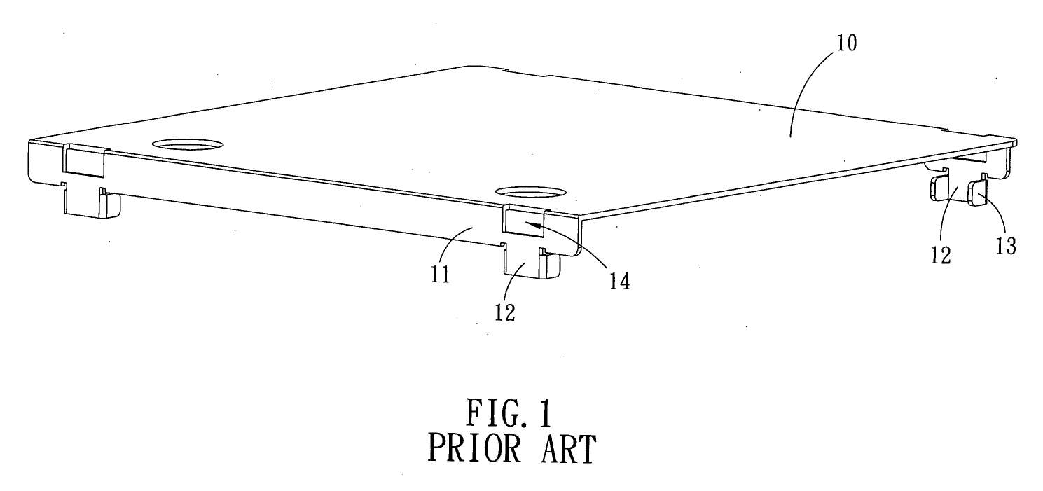

FIG. 2 is a perspective view of showing laminated radiating fins in accordance with the present invention;

FIG. 3 is a partial exploded view of the radiating fin in accordance with the present invention;

FIG. 4 is another partial exploded view of the radiating fin in accordance with the present invention; and

FIG. 5 is assembly cross sectional view of showing the laminated radiating fins in accordance with the present invention.

### DETAILED DESCRIPTION OF THE PREFERRED EMBODIMENTS

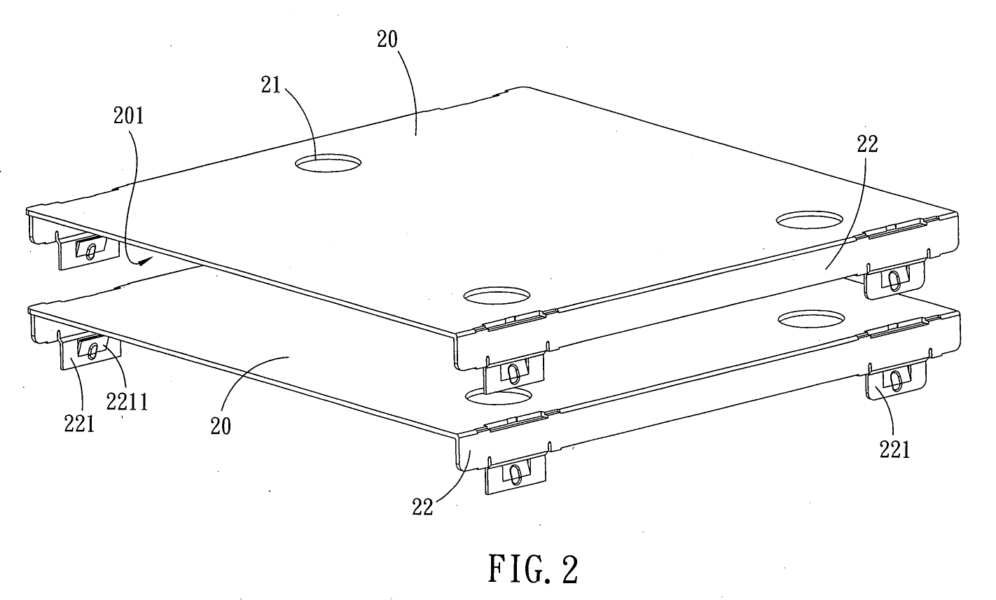

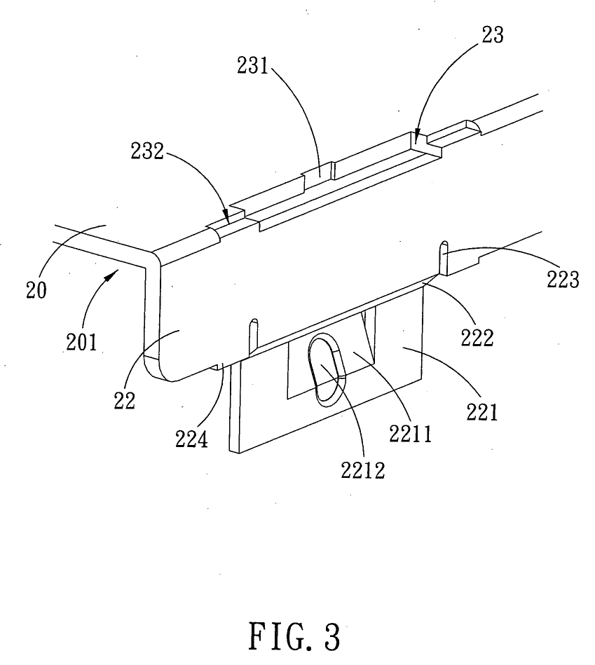

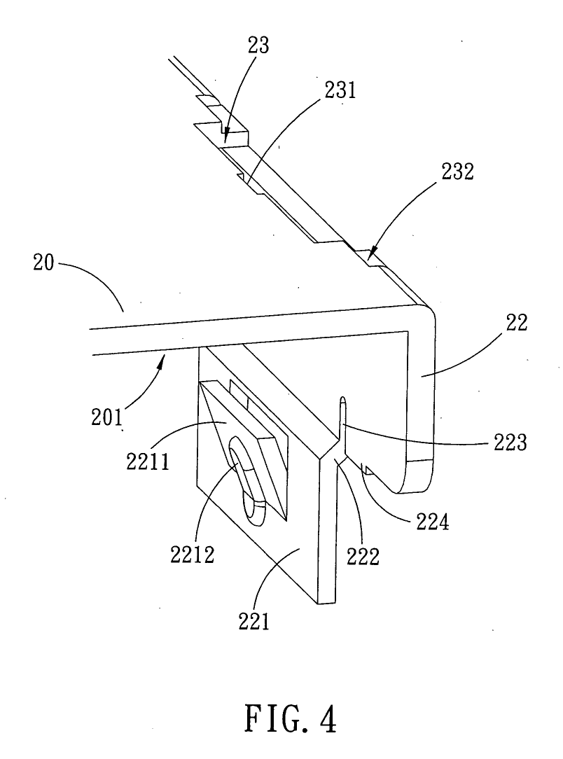

Referring to FIGS. 2-5, a radiating fin assembly in accordance with the present invention comprises a plurality of radiating fins 20 stacked together.

The radiating fin 20 is a plate formed with a plurality of guiding holes 21 at the upper surface thereof. At two opposite sides of the radiating fin 20 is formed a folding edges 22, and at both ends of the folding edge 22 is formed a locking protrusion 221 connected to the folding edge 22 by an inward inclined neck portion 222. A flexible slot 223 is defined in the folding edge 22 and located at both sides of the locking protrusion 221, and a plurality of notches 23 are defined in the radiating fin 20 and located correspondingly to the locking protrusions 221, so that the locking protrusions 221 of one radiating fin 20 can be engaged in the notches 23 of another radiating fin 20.

A flexible hook 2211 is formed on each of the locking protrusions 221 and located correspondingly to the undersurface 201 of the radiating fin 20, one side of the flexible hook 2211 is connected with the locking protrusion 221, and a rib 2212 is disposed on the flexible hook 2211 and connected to the locking protrusion 221. A guiding channel 231 is formed in the notch 23 for mating with the rib 2212.

At both sides of the notch 23 is formed a positioning groove 232 (one of the aforesaid positioning member), respectively, and a protruding positioning block 224 (one of the aforesaid positioning member) is formed near each of the flexible slots 223 of the edge of the locking protrusion 221 and is to be pushed into the positioning groove 232 when two radiating fins 20 are assembled to each other.

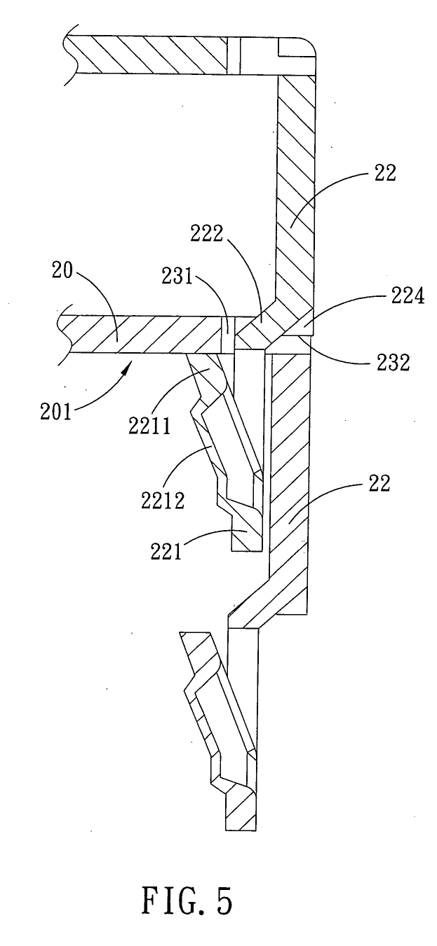

For a better understanding of the present invention, its operations and functions, references should be made to FIGS. 2 and 5, when assembling two radiating fins 20 together, initially, the user can insert tools into the guiding holes 21 of a first radiating fin 20, and then introduce it into a second radiating fin 20. At this moment, the inclined inward neck portion 222 of the locking protrusion 221 of the second radiating fin 20 will face toward the notch 23, and the rib 2212 of the flange 221 will be guided into the guiding channel 231 of the notch 23, so that the flexible hook 2211 can be compressed and guided into the notch 23 smoothly. And then, under the effect of its own flexibility and the rib 2212, the flexible hook 2211 will restore its original shape immediately after being inserted into the notch 23, and the restored flexible hook 2211 will press against the undersurface 201 of the radiating fins 20. In this way, a plurality of radiating fins 20 can be assembled together. When disassembling the assembly of the radiating fins 20, the user only needs to press the flexible hook 2211 so as to make it disengage from the notch 23. By such arrangements, not only the flexible hook. 2211 can be prevented from distortion, but also the radiating fins 20 can be assembled to and disassembled from each other very conveniently.

It still to be noted that since the rib 2212 of the flexible hook 2211 of the locking protrusion 221 is guided by the guiding channel 231 of the notch 23, the flexible hook 2211 can be positioned firmly (prevented from distortion). Besides, the positioning block 224 of the locking protrusion 221 of the radiating fin 20 will be pushed against the positioning grooves 232 of another radiating fin 20, thereby stability of the radiating fin assembly of the present invention is improved, and the problems of loose engagement and distortion in parallel degree also can be eliminated.

While we have shown and described various embodiments in accordance with the present invention, it should be clear to those skilled in the art that further embodiments may be made without departing from the scope of the present invention.

What is claimed is:

1. A radiating fin assembly comprising a plurality of radiating fins stacked together, wherein:
a folding edge is formed on opposite sides of each of the radiating fins, respectively, at both ends of the folding edge is formed a locking protrusion being connected to the folding edge by an inward inclined neck portion, a flexible slot is defined in the folding edge and located at both sides of the locking protrusion, and a plurality of notches are defined in the radiating fin and located correspondingly to the locking protrusion, so that the locking protrusion of one radiating fin will be engaged in the notches of another radiating fin after two radiating fins are assembled together; and
a flexible hook is formed on the locking protrusion and located correspondingly to a undersurface of the radiating fin, one side of the flexible hook is connected to the locking protrusion, and a rib is disposed on the flexible hook and connected to the locking protrusion, and at both sides of the locking protrusion and the notches are correspondingly arranged a plurality of positioning members

2. The radiating fin assembly as claimed in claim 1, wherein a plurality of guiding holes are defined in each of the radiating fins, so that tools are allowed to be inserted through the guiding holes for quick assembly of the radiating fins together.

3. The radiating fin assembly as claimed in claim 1, wherein a guiding channel is formed in each of the notches for mating with the rib.

4. The radiating fin assembly as claimed in claim 1, wherein the positioning members at both sides of the locking protrusion and the notches are positioning grooves and positioning blocks, and the positioning blocks of one radiating fin are to be engaged in the positioning grooves of another radiating fin when two radiating fins are assembled to each other.
